(19) United States
(12) Patent Application Publication
(10) Pub. No.: US 2023/0028297 A1
(43) Pub. Date: Jan. 26, 2023

(54) METHODS OF FORMING AN APPARATUS COMPRISING SILICON CARBIDE MATERIALS AND RELATED MICROELECTRONIC DEVICES AND SYSTEMS

(71) Applicant: Micron Technology, Inc., Boise, ID (US)

(72) Inventors: Vivek Yadav, Boise, ID (US); Silvia Borsari, Boise, ID (US); Song Guo, Boise, ID (US)

(21) Appl. No.: 17/813,076

(22) Filed: Jul. 18, 2022

Related U.S. Application Data
(60) Provisional application No. 63/225,188, filed on Jul. 23, 2021.

(51) Int. Cl. H01L 27/108

(52) U.S. Cl. CPC H01L 27/10888; H01L 27/10814

(57) ABSTRACT

A method of forming a semiconductor device comprising forming a silicon carbide material on a patterned material. The silicon carbide material is subjected to a plasma to expose horizontal portions of the silicon carbide material to the plasma. The horizontal portions of the silicon carbide material are selectively removed, and the patterned material is removed to form a pattern of the silicon carbide material.

### CROSS-REFERENCE TO RELATED APPLICATION

This application claims the benefit under 35 U.S.C. § 119(e) of U.S. Provisional Patent Application Ser. No. 63/225,188, filed Jul. 23, 2021, the disclosure of which is hereby incorporated herein in its entirety by this reference.

### TECHNICAL FIELD

Embodiments disclosed herein relate to an apparatus and methods of forming an apparatus. More particularly, embodiments of the disclosure relate to methods of using a silicon carbide material as a liner, and to related apparatus containing the silicon carbide material.

### BACKGROUND

Electronic device designers desire to increase the level of integration or density of features within an electronic device by reducing the dimensions of individual features and by reducing the separation distance between neighboring features. In addition, electronic device designers often desire to design architectures that are not only compact, but offer performance advantages, as well as simplified designs. A relatively common electronic device is a memory device. A memory device may include a memory array having a number of memory cells arranged in a grid pattern. One type of memory cell is a dynamic random access memory (DRAM) device, which is a volatile memory device that may lose a stored state over time unless the DRAM device is periodically refreshed by an external power supply. In the simplest design configuration, a DRAM cell includes one access device (e.g., a transistor) and one storage device (e.g., a capacitor). Modern applications for memory devices may utilize vast numbers of DRAM unit cells, arranged in an array of rows and columns. The DRAM cells are electrically accessible through digit lines and wordlines arranged along the rows and columns of the array.

Dry etch processes are used in many memory device fabrication processes due to directionality of the plasma that is achieved during the dry etch process. The plasma directionality of the dry etch process enables materials to be etched to exhibit vertical sidewalls. The dry etch processes are used, for example, in pitch multiplication processes, where a spacer material is formed and portions removed to expose underlying materials. Such processes are known in the art as so-called “punch processes” because the spacer material is punched through to expose the underlying materials. However, dry etch processes have drawbacks including causing surface damage to underlying materials, and having low etch selectivities between exposed materials due to ion bombardment. When dry etch processes are used in pitch multiplication processes, variations may also occur in depth and spacing of a pattern of the spacer material. The resulting spacers may also exhibit tapered (e.g., faceted) profiles or spacer clipping, resulting in rounded edges of the spacers.

### BRIEF DESCRIPTION OF THE DRAWINGS

FIGS. 1A through 1D are simplified partial cross-sectional views showing a method of forming an apparatus in accordance with embodiments of the disclosure;

FIGS. 2A and 2B are a simplified partial cross-sectional views showing a method of forming an apparatus in accordance with embodiments of the disclosure;

FIG. 3 is a simplified block diagram of a microelectronic device (e.g., a DRAM device, a memory device) including an apparatus in accordance with embodiments of the disclosure;

FIGS. 4A and 4B are cross-sectional views of a portion of a microelectronic device (e.g., a DRAM device, a memory device) including an apparatus in accordance with embodiments of the disclosure; and

FIG. 5 is a simplified block diagram of a system implemented in accordance with some embodiments of the disclosure.

### DETAILED DESCRIPTION

An apparatus (e.g., a microelectronic device, a semiconductor device, a memory device) that includes a liner adjacent to (e.g., over) one or more materials is disclosed. The liner includes a silicon-containing material that also contains carbon atoms (e.g., a silicon carbide material). The silicon-containing material of the liner is formed over a patternable material and a patterned material (e.g., a patterned mandrel material), where the patterned material overlies the patternable material. The silicon-containing material of the liner is conformally formed. After formation, portions of the silicon-containing material are exposed to a plasma treatment act, which changes a chemical composition of the exposed portions of the liner. After the plasma treatment, the exposed portions of the liner are selectively removed (e.g., selectively etched) by a wet etch act. By conducting the plasma treatment act on the silicon-containing material as initially formed, the exposed portions and unexposed portions of the liner may exhibit different chemical compositions, enabling the exposed portions of the liner to be selectively removed by the wet etch act while the unexposed portions of the liner remain. The remaining portions of the liner may be oriented substantially vertically to a base material on which the patternable material and the patterned material are located. The remaining portions of the liner may exhibit substantially square corners distal to the base material and be of substantially uniform heights and spacing.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed by conventional techniques.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an” and “the” are intended to include the plural forms as well, unless the context clearly indicates otherwise.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “conductive material” means and includes an electrically conductive material. The conductive material may include, but is not limited to, one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), n-doped polysilicon, p-doped polysilicon, undoped polysilicon, and conductively doped silicon.

As used herein, the term “configured” refers to a size, shape, material composition, and arrangement of one or more of at least one structure and at least one apparatus facilitating operation of one or more of the structure and the apparatus in a pre-determined way.

As used herein, the term “dielectric material” means and includes an electrically insulative material. The dielectric material may include, but is not limited to, one or more of an insulative oxide material or an insulative nitride material. A dielectric oxide may be an oxide material, a metal oxide material, or a combination thereof. The dielectric oxide may include, but is not limited to, a silicon oxide (SiOₓ, silicon dioxide (SiO₂)), doped SiOₓ, phosphosilicate glass, borosilicate glass, borophosphosilicate glass, fluorosilicate glass, tetraethylorthosilicate (TEOS), aluminum oxide (AlOₓ), gadolinium oxide (GdOₓ), hafnium oxide (HfOₓ), magnesium oxide (MgOₓ), niobium oxide (NbOₓ), tantalum oxide (TaOₓ), titanium oxide (TiOₓ), zirconium oxide (ZrOₓ), hafnium silicate, a dielectric oxynitride material (e.g., SiOₓN_{y}), a dielectric carboxynitride material (e.g., SiOₓC_{z}N_{y}), a combination thereof, or a combination of one or more of the listed materials with silicon oxide. A dielectric nitride material may include, but is not limited to, silicon nitride.

As used herein, the terms “different chemical compositions” or “different material compositions” mean and include a chemical composition of a portion of a liner material differing in the relative ratio of one or more chemical elements from a chemical composition of another portion of the liner material. For example, if the liner material is a doped silicon-containing material, the chemical composition, one portion of the liner material may include a higher carbon content than another portion of the liner material.

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may be a 3D electronic device, such as a 3D DRAM device.

As used herein, the term “liner material” or “liner” means and includes a silicon carbide material or a doped silicon-containing material, such as a doped silicon carbide material, formulated to exhibit etch selectivity relative to other exposed materials when subjected to the same etch conditions. The liner may include one or more materials, such as a silicon carbide material, a silicon carbon oxide material, a silicon carbon nitride material, a silicon carbon boride material and one or more other materials, positioned adjacent to one another and that are formulated to exhibit the desired etch selectivity properties.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the term “silicon carbide material” means and includes a material including silicon atoms and carbon atoms, and, optionally one or more of oxygen atoms, nitrogen atoms, or boron atoms. Therefore, the term includes silicon carbide, silicon carbon oxide, silicon carbon nitride, silicon carbon oxynitride, or silicon carbon boride. The term “silicon carbide material” may also be used to collectively refer to silicon carbide (SiC) or the doped silicon carbide material.

As used herein, the term “doped silicon carbide material” means and includes a material including silicon atoms, carbon atoms, and one or more of oxygen atoms, nitrogen atoms, or boron atoms. The doped silicon carbide material may include, but is not limited to, a silicon carbon oxide material, a silicon carbon nitride material, or a silicon carbon oxynitride material. The doped silicon carbide material may also include a silicon carbon boride material or a silicon carbon oxyboride carbide material. The term “silicon carbon oxide” is used to refer to the doped silicon carbide material having a general chemical formula of SiC_{y}Oₓ, wherein one or more of the carbon atoms are bonded to the silicon atoms. The term “silicon carbon nitride” is used to refer to the doped silicon carbide material having a general chemical formula of SiCN_{y}, and the term “silicon carbon oxynitride” is used to refer to the doped silicon carbide material having a general chemical formula of SiCOₓN_{y}. The doped silicon carbide materials listed above may be a stoichiometric compound or a non-stoichiometric compound, and values of “x” and “y” may be integers or may be non-integers. The term “doped silicon carbide material” is used to collectively refer to the silicon carbon oxide material, the silicon carbon nitride material, and/or the silicon carbon oxynitride material. Silicon oxide (SiOₓ) including only silicon atoms and oxygen atoms is excluded from the definition of a doped silicon carbide material.

As used herein, the term “selectively etchable” means and includes a material that exhibits a greater etch rate responsive to exposure to a given etch chemistry and/or process conditions relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a material (e.g., a base material) or construction upon which additional materials are formed. The substrate may be a an electronic substrate, a semiconductor substrate, a base semiconductor layer on a supporting structure, an electrode, an electronic substrate having one or more materials, layers, structures, or regions formed thereon, or a semiconductor substrate having one or more materials, layers, structures, or regions formed thereon. The materials on the electronic substrate or semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOT”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art.

Unless the context indicates otherwise, the removal of materials described herein may be accomplished by any suitable technique including, but not limited to, etching (e.g., dry etching, wet etching, vapor etching), ion milling, abrasive planarization, or other known methods.

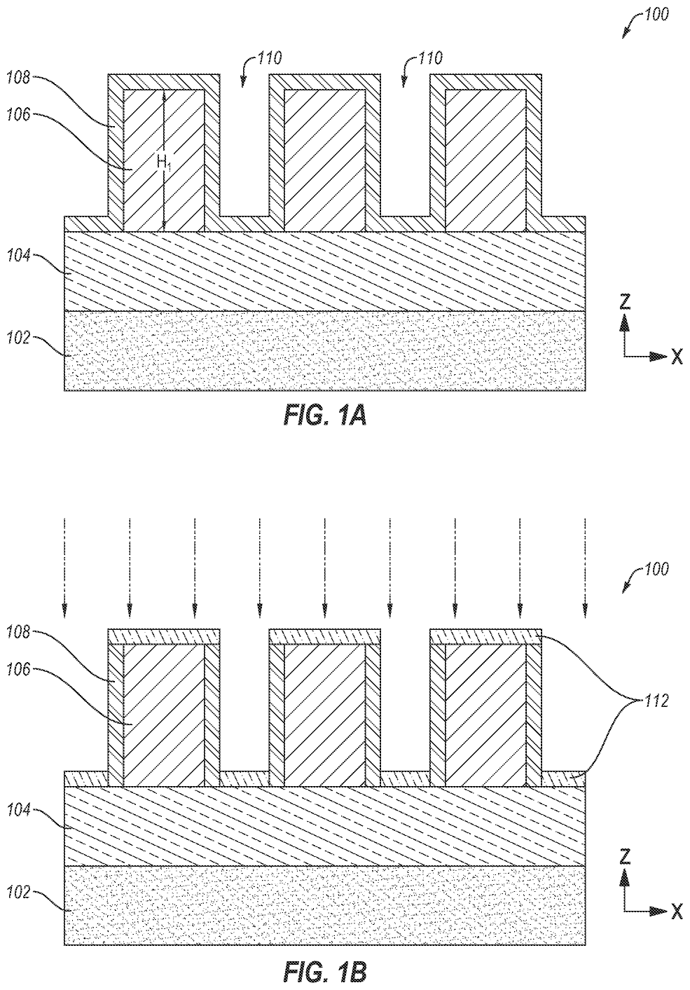

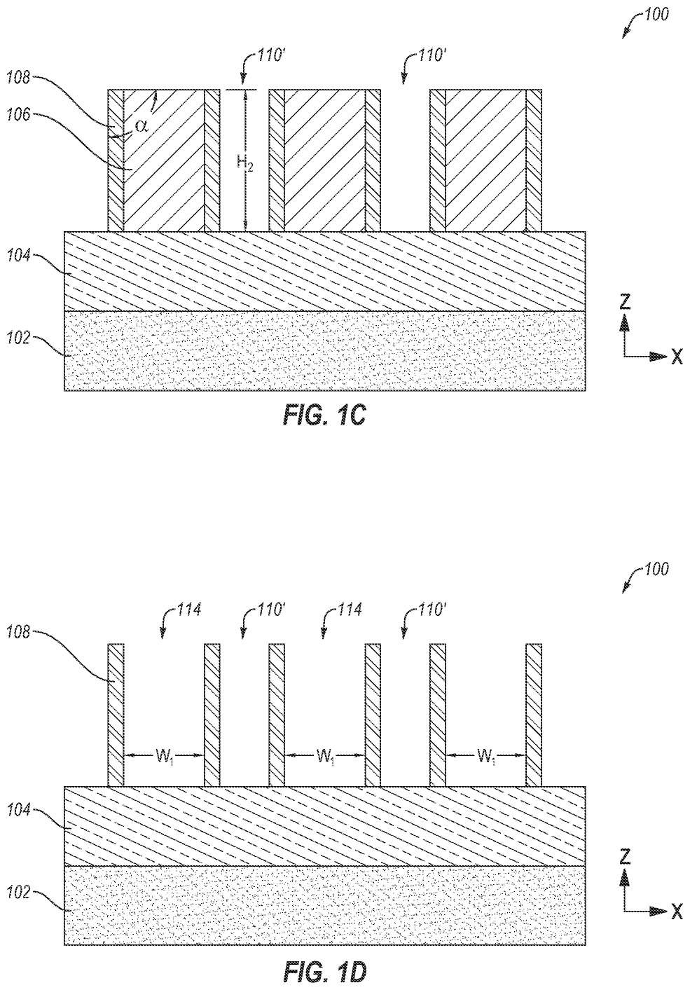

FIGS. 1A through 1D are simplified partial cross-sectional views showing embodiments of a method of forming an apparatus 100 (e.g., a microelectronic device; a semiconductor device; a memory device, such as a DRAM device). With the description provided below, it will be readily apparent to one of ordinary skill in the art that the methods described herein may be used to form various devices. In other words, the methods of the disclosure may be used whenever it is desired to form an apparatus.

Referring to FIG. 1A, an apparatus 100 may include a base material 102, a patternable material 104, a patterned mandrel material 106, a liner 108, and openings 110. As shown in FIG. 1A, the patternable material 104 may be formed on or over (e.g., in the X-direction) the base material 102, and the mandrel material (not shown) may be formed on or over (e.g., in the X-direction) the patternable material 104. The mandrel material (not shown) may be patterned to form the patterned mandrel material 106. The liner 108 may be formed on or over surfaces (e.g., upper surfaces, side surfaces) of the patterned mandrel material 106, and on or over upper surfaces of the patternable material 104. Openings 110 may vertically extend (e.g., in the Z-direction) between and separate adjacent portions of the patterned mandrel material 106, and may terminate (e.g., end) at upper surfaces of the liner 108.

The base material 102, the patternable material 104, and the mandrel material may be formed using conventional processes, such as in situ growth, spin-on coating, blanket coating, CVD, PECVD, ALD, or PVD. By way of non-limiting example, the base material 102 may be formed of and include silicon. The patternable material 104 and the material of the patterned mandrel material 106 may be selectively etchable relative to one another. The patternable material 104 may be formed of and include a conductive material, such as a metal or a metal alloy, or a dielectric material. The mandrel material may be formed of and include a material that is substantially free of carbon and that may be selectively etchable relative to the liner 108. Additionally, the mandrel material may exhibit resistance to plasma conditions. By way of non-limiting example, the mandrel material, may be formed of and include polycrystalline silicon or amorphous silicon.

The base material 102, the patternable material 104, and the mandrel material may each individually be formed to a desired thickness (e.g., height in the Z-direction). The base material 102, the patternable material 104, and the mandrel material may each exhibit substantially the same thickness as one another; or one or more of the base material 102, the patternable material 104, and the mandrel material may exhibit a different thickness than one or more other of the base material 102, the patternable material 104, and the mandrel material. The In some embodiments, the thickness of the patternable material 104 is less than the thickness of the base material 102 and greater than the thickness of the mandrel material. In addition, the base material 102, the patternable material 104, and the mandrel material may each individually be substantially uniform throughout the thickness thereof; or one or more (e.g., each) of the base material 102, the patternable material 104, and the mandrel material may be non-uniform throughout the thickness thereof. In some embodiments, the base material 102, the patternable material 104, and the mandrel material are each formed to be substantially uniform throughout the thickness thereof.

After formation, the mandrel material may be subjected to conventional patterning processes, such as conventional photolithography processes, or spin-on-carbon and electron-beam lithography processes, to form the patterned mandrel material 106 as shown in FIG. 1A. A pattern of the patterned mandrel material 106 may at least partially depend on desired dimensions of features to be formed in the materials below the patterned mandrel material 106 during subsequent processing of the apparatus 100. In some embodiments, the pattern of the mandrel material 106 corresponds to a pattern of features ultimately to be formed in the apparatus 100. The patterned mandrel material 106 may exhibit a height H₁.

With continued reference to FIG. 1A, the liner 108 may be formed over exposed surfaces of the patternable material 104 and the patterned mandrel material 106. For example, as shown in FIG. 1A, the liner 108 may extend (e.g., continuously extend) over surfaces of the patterned mandrel material 106 and the upper surfaces of the patternable material 104. The liner 108 may at least partially (e.g., substantially) conform to a topography defined by the exposed surfaces of the patternable material 104 and the patterned mandrel material 106. In some embodiments, opposing side surfaces (e.g., opposing sidewalls) of the liner 108 are parallel to each other, and lower horizontally oriented surfaces of the liner 108 extend between the opposing side surfaces of the liner 108 in a direction perpendicular, or at least substantially perpendicular to the opposing side surfaces of the liner 108. The liner 108 partially (e.g., less than completely) fills the openings 110.

The openings 110 may be at least partially defined by opposing side surfaces (e.g., opposing sidewalls) of the liner 108 and by horizontally oriented portions of the liner 108. For example, the opposing side surfaces of the liner 108 may at least partially define vertical boundaries (e.g., in the Z-direction) of the openings 110; lower horizontally oriented surfaces of the liner 108 may at least partially define lower horizontal boundaries (e.g., in the X-direction) of the openings 110; and the upper horizontally oriented surfaces of the liner 108 may define upper horizontal boundaries (e.g., in the X-direction) of the openings 110. The openings 110 may exhibit any desired shape and dimensions (e.g., height in the Z-direction, width in the X-direction, and length in another horizontal direction orthogonal to the X-direction). The shape and dimensions of the openings 110 may at least partially depend upon the shapes and dimensions of additional structures to be formed within the openings 110.

The liner 108 may be formed of and include a silicon carbide material or a doped silicon carbide material such as, SiC, silicon carbon oxide (SiC_{y}Oₓ), or silicon carbon nitride (SiCN_{y}), wherein an atomic percentage (at. %) of carbon within the liner 108 is within a range of from about 0.1 at. % to about 20 at. %, such as from about 1 at. % to about 15 at. %, from 6 at. % to about 15 at. %, from about 6 at. % to about 20 at. %, from about 10 at. % to about 20 at. %, from about 10 at. % to about 15 at. %, or from about 8 at. % to about 10 at. %. The liner 108 may be formed by CVD, ALD, or other technique suitable for forming the liner 108 at a desired thickness and at a high degree of conformality. In some embodiments, the liner 108 is silicon carbon oxide, where one or more of the carbon atoms of the silicon carbon oxide are bonded to the silicon atoms. In other embodiments, the liner 108 is silicon carbon nitride. The liner 108 may be formed at a temperature of from about 200° C. to about 700° C., such as from about 300° C. to about 600° C., or from about 375° C. to about 550° C.

A thickness of the liner 108 may at least partially depend on the dimensions (e.g., width in the X-direction, height in the Z-direction) of the openings 110 and on dimensions of additional materials to be formed within the openings 110. The thickness of the liner 108 may at least partially depend on the dimensions of features to be formed in the materials below the liner 108 during subsequent process acts for forming the apparatus (e.g., the electronic device). The liner 108 may be formed at a minimum thickness that provides a substantially continuous material over the patternable material 104 and the patterned mandrel material 106. In other words, the liner 108 does not include gaps, pinholes, etc. The liner 108 may be formed at a thickness within a range of from about 1 nm to about 15 nm, such as from about 1 nm to about 10 nm, from about 1 nm to about 8 nm, from about 1 nm to about 7 nm, from about 3 nm to about 10 nm, or from about 3 nm to about 8 nm. Since the liner 108 is formed at a high degree of conformality, the liner 108 is substantially uniform in its thickness.

Referring next to FIG. 1B, the liner 108 may be subjected to (e.g., exposed to) one or more treatment acts (indicated by arrows) that change (e.g., reduce) the carbon content of the liner 108, which changes the chemical composition of portions of the liner 108 compared to the composition of the liner 108 as initially formed. The treatment act may include exposing the liner 108 to a plasma treatment act (e.g., an oxygen gas (O₂) plasma treatment act). For example, oxygen atoms of the plasma treatment replace the carbon atoms of the liner material, therefore reducing the carbon content of the liner 108. The portions of the liner 108 exposed to the plasma may be the portions of the liner 108 on the horizontal surfaces of the patterned mandrel material 106, and portions of the liner 108 on the upper horizontal surfaces of the patternable material 104. For instance, the portions of the liner 108 adjacent to (e.g., over) the horizontal surfaces of the patterned mandrel material 106, and the portions of the liner 108 adjacent to (e.g., over) the horizontal surfaces of the patternable material 104 may be exposed to the plasma, while portions of the liner 108 on the sidewalls of the patterned mandrel material 106 of the apparatus 100 are not substantially exposed to the plasma. Following the plasma treatment act, the exposed portions (e.g., horizontal portions) of the liner 108 exhibit a decreased amount of carbon relative to the unexposed portions (e.g., vertical portions) of the liner 108. By way of example only, the horizontal portions of the liner 108, following exposure to the plasma, may be substantially free of carbon, such that the horizontal portions of the liner 108 include no (e.g., 0 at. %) carbon.

To prevent damage to the vertical portions of the liner 108, the plasma treatment act may be a highly directional plasma treatment act where the direction of the flow of ions is controlled (e.g., biased). A bias may be used to selectively expose the horizontal portions of the liner 108 to the plasma. Therefore, only the horizontally-oriented portions of the liner 108 are reduced in carbon content. The vertically-oriented portions of the liner 108 remain substantially unaffected following the plasma treatment act and exhibit a material composition that is substantially the same as the material composition of the liner 108 as initially formed. The portions (e.g., treated liner portions 112) of the liner 108 affected (e.g., damaged) by the plasma treatment exhibit a material composition that is different from the material composition of the liner 108 as initially formed.

The plasma may be a reducing plasma that includes, but is not limited to, an O₂ plasma, an O₂/hydrogen gas (H₂)/nitrogen gas (N₂) plasma, an H₂/N₂ plasma, or an O₂/fluorocarbon plasma. The plasma may also include an inert gas, such as argon. Process conditions for the plasma treatment act, such as time, RF power, exhaust power, gas mixture, flow rate, etc., may be chosen depending on the composition of the plasma utilized for the treatment act. In addition, the shape and dimensions of the openings 110 may affect the process conditions utilized during the plasma treatment act. For instance, an opening with a smaller dimension in the X-direction than another opening of the same dimension in the Z-direction and a larger dimension in the X-direction may utilize increased RF power, increased exhaust power, and an increased flow rate to provide the same amount of damage to the horizontal portions of the liner. In some embodiments, the plasma includes 100 weight percent (wt %) 02.

The horizontal portions of the liner 108 exposed to the plasma are referred to as the treated liner portions 112, and are shown in FIG. 1B and subsequent drawings as treated liner portions 112, indicating that the plasma treatment act has been conducted. The treated liner portions 112 exhibit a reduced carbon content than the remaining (e.g., untreated) portions of the liner 108 as a result of the plasma treatment. After conducting the plasma treatment, the treated liner portions 112 may contain substantially no carbon. Exposing the liner 108 to the plasma decreases the carbon content in the portions of the liner 108 and increases the oxygen content. Without being bound by any theory, the silicon carbon oxide material of the liner 108 is converted to a silicon oxide (SiOₓ) material by the plasma, which is selectively removable (e.g., selectively etchable) relative to the untreated portions of the liner 108. The different chemical compositions of the treated liner portions 112 and the remaining portions of the liner 108 provide etch selectivity during subsequent process acts.

Referring next to FIG. 1C, the treated liner portions 112 may be selectively removed from the horizontal surfaces of the patterned mandrel material 106 and from the upper surfaces of the patternable material 104. For instance, the treated liner portions 112 adjacent to (e.g., over) the horizontal surfaces of the patterned mandrel material 106 and adjacent to (e.g., over) the horizontal surfaces of the patternable material 104 may be removed, while the portions of the liner 108 remain on the sidewalls of the patterned mandrel material 106 of the apparatus 100. The treated liner portions 112 may be removed (e.g., etched) by a selective etch (e.g., an isotropic etch) process, such as a wet etch process or a vapor etch process. By way of non-limiting example, the treated liner portions 112 may be removed by a wet etch process. The remaining liner 108 may exhibit substantially vertical sidewalls and substantially square corners following the wet etch process. In other words, an angle α defined by an intersection between an upper surface of the liner 108 and a sidewall of the liner 108 may range between about 85 degrees and about 100 degrees, such as between about 87 degrees and about 95 degrees, or between about 88 degrees and about 93 degrees. In some embodiments, the angle is about 90 degrees. The remaining portions of the liner 108 may exhibit substantially similar heights H₂ as one another. The heights H₂ of the liner 108 may range between about 95% and about 105% of the height H₁ of the patterned mandrel material 106. In contrast, if the treated liner portions 112 were removed by a conventional dry etch process, the remaining liner would include rounded corners, faceting of top portions of the liner sidewalls, and tapered sidewalls. In addition, portions of the liner remaining following the conventional dry etch process would be present at differing heights and spacings.

By way of non-limiting example, if the liner 108 is a silicon carbon oxide material, the treated liner portions 112 may be removed using an aqueous hydrogen fluoride (HF) solution. The etch chemistry and etch conditions may be selected to substantially remove the treated liner portions 112, while the liner 108 remains on the sidewalls of the patterned mandrel material 106. The patterned mandrel material 106 and the patternable material 104 may be substantially unaffected by the etch chemistry and etch conditions. While FIG. 1A shows the liner 108 as being a substantially continuous material, the liner 108 shown in FIG. 1C becomes discontinuous following the wet etch process.

With continued reference to FIG. 1C, openings 110′ are formed in apparatus 100 where openings 110 previously existed (see FIG. 1A). The openings 110′ may be at least partially defined by opposing side surfaces (e.g., opposing sidewalls) of the remaining portions of the liner 108 and by horizontal surfaces of the patternable material 104. For example, the opposing side surfaces of the remaining portions of the liner 108 may at least partially define vertical boundaries (e.g., in the Z-direction) of the openings 110′; lower horizontal surfaces of the patternable material may at least partially define lower horizontal boundaries (e.g., in the X-direction) of the openings 110′; and the upper horizontally oriented surfaces of the remaining portions of the liner 108 may define upper horizontal boundaries (e.g., in the X-direction) of the openings 110′. The openings 110′ may exhibit any desired shape and dimensions (e.g., height in the Z-direction, width in the X-direction, and length in another horizontal direction orthogonal to the X-direction). The shape and dimensions of the openings 110′ may at least partially depend upon the shapes and dimensions of additional structures to be formed within the openings 110′. By way of non-limiting example, the openings 110′ may exhibit a columnar shape (e.g., a substantially rectangular columnar cross-sectional shape), a width (e.g., in the X-direction) less than 10 nm, and a height (e.g., in the Z-direction) greater than or equal to about one (1) times the width (e.g., a height to width ratio within a range of from about 1:1 to about 20:1, such as from about 2:1 to about 10:1, from about 5:1 to about 15:1, or from about 5:1 to about 10:1).

Referring next to FIG. 1D, the patterned mandrel material 106 overlying the patternable material 104 may be removed to form a pattern of core spaces 114 and the liner 108, and to expose underlying portions of the patternable material 104. The remaining portions of the liner 108 may exhibit substantially similar core spacings Wi.

The liner 108 may be used as a spacer material in a spacer etch process, as illustrated in FIGS. 1A-1D. Conducting the plasma treatment act and the wet etch act on the liner 108 enables corner regions of the remaining portions of the liner 108 (FIGS. 1C, 1D) to be substantially square in cross-section. In addition, the treated liner portions 112 may be removed without damaging the patterned mandrel material 106 or the patternable material 104. The combination of the plasma treatment act and the wet etch act produce desired profiles of spacers compared to conventional dry etch processes. The remaining portions of the liner 108 may be utilized as a mask to transfer the pattern of core spaces 114 and the liner 108 into underlying materials, such as the patternable material 104 or into the base material. Therefore, methods according to embodiments of the disclosure may be used to form a pattern of spacers without conducting a dry etch process to punch through the spacer materials without affecting (e.g., reducing) directionality of the removal process. Additional processing acts may be performed to achieve the desired structure of apparatus 100.

Accordingly, a method of forming an apparatus is disclosed. The method comprises forming a silicon carbide material on a patterned material. The silicon carbide material is subjected to a plasma to expose horizontal portions of the silicon carbide material to the plasma. The horizontal portions of the silicon carbide material are selectively removed, and the patterned material is removed to form a pattern of the silicon carbide material.

Accordingly, another method of forming an apparatus is disclosed. The method comprises forming a silicon carbon oxide material on a structure comprising a first material and a dielectric material. The silicon carbon oxide material is exposed to a plasma, with horizontal portions of the silicon carbon oxide material exposed to a greater concentration of ions of the plasma than vertical portions of the silicon carbon oxide material. The horizontal portions of the silicon carbon oxide material are removed without substantially removing the vertical portions of the silicon carbon oxide material to expose the first material.

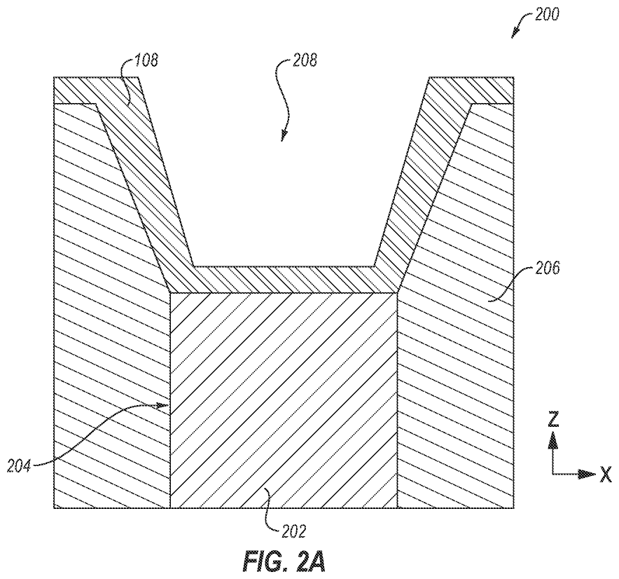

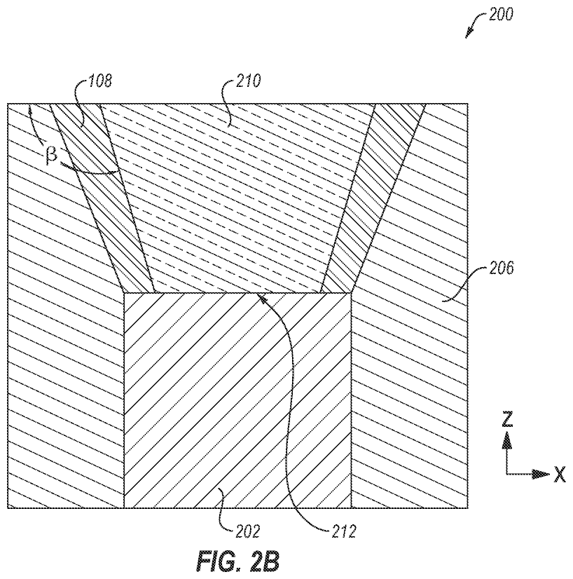

The methods according to embodiments of the disclosure may also be used to reduce damage at interfaces between different, adjacent materials. The remaining portions of the liner 108 may be present in an apparatus 200, as shown in FIGS. 2A and 2B. In FIG. 2A, a first material 202 is formed in a first opening 204 in a dielectric material 206. The first material 202 may be a conductive material, or a semiconductor material. A second opening 208 is formed adjacent to (e.g., over) the first material 202 and the liner 108 is conformally formed in the second opening 208. The second opening 208 may be defined by sloped sidewalls of the dielectric material 206, in contrast to the substantially vertical sidewalls of apparatus 100 in FIGS. 1A-1D. The liner 108 may be subjected to the plasma treatment act and the wet etch act, as described above for FIGS. 1A-1D, to selectively expose and remove horizontal portions of the liner 108 over the first material 202 and over the dielectric material 206. During the plasma treatment act, the horizontal portions of the liner 108 are exposed to the plasma to a greater extent than portions of the liner 108 within the second opening 208, forming treated liner portions (not shown). The carbon in the horizontal portions of the liner 108 is removed by the plasma, converting the silicon carbon oxide material of the liner 108 to the silicon oxide material, which is selectively removed by the wet etch process, as shown in FIG. 2B. The differing carbon content in the liner 108 and the treated liner portions (not shown) enables the selective removal of the treated liner portions, exposing underlying portions of the first material 202 and the dielectric material 206. The liner 108 remaining in the second opening 208 may, therefore, exhibit substantially square corners or corners that exhibit an angle greater than 90 degrees (i.e., an obtuse angle). For instance, an angle θ defined by the intersection between an upper surface of the dielectric material 206 and a sidewall of the liner 108 remaining in the second opening 208 may be greater than or equal to equal to about 95 degrees, such as from about 95 degrees to about 100 degrees. If the angle θ is greater than 100 degrees (100°), the liner 108 on the sidewalls of the dielectric material 206 may be partially exposed to the plasma treatment act and subsequently a portion of the liner 108 on the sidewalls of the dielectric material 206 may be removed by the wet etch act. A second material 210 is formed in the second opening 208, adjacent to (e.g., laterally adjacent to) the liner 108 and adjacent to (e.g., vertically adjacent to) the first material 202. The second material 210 may be a conductive material, a dielectric material, or a semiconductor material. The apparatus 200 includes the first material 202 and the second material 210 in direct contact with one another and the liner 108 between the second material 210 and the dielectric material 206. The liner 108 may be present on sloped sidewalls of the dielectric material 206. The liner 108 may also contact an upper surface of the first material 202. An interface 212 between the first material 202 and the second material 210 is substantially free of damage to the first material 202.

By using the plasma treatment act and the wet etch act to form and selectively remove the treated liner portions (not shown), the first material 202 is not substantially damaged during the removal of desired portions (e.g., the treated liner portions) of the liner 108. Therefore, an interface 212 between the first material 202 and the second material 210 may be improved relative to an interface between the first material 202 and the second material 210 if a conventional dry etch process was conducted to remove the desired portions of the liner 108. The improved interfacial properties may improve electrical performance properties of the apparatus 200. In some embodiments, the first material 202 and the second material 210 are conductive materials and the improved interface between the materials results in a lower contact resistance during use and operation of the apparatus 200. The first material 202 and the second material 210, in such embodiments, may be configured as interconnects (e.g., contacts) in a DRAM device or other memory device. Alternatively, the apparatus 200 may be used in other microelectronic devices, such as logic devices, where lower contact resistance between adjacent conductive materials is desired. In other embodiments, the first material 202 is a conductive material and the second material 210 is a conductive material. The conductive material of the first material 202 may be the same material or a different material than the conductive material of the second material 210. Using the plasma treatment act and the wet etch also enables the improved interface 212 to be achieved even when the second opening 208 has a high aspect ratio, such as an aspect ratio of greater than or equal to about 20:1.

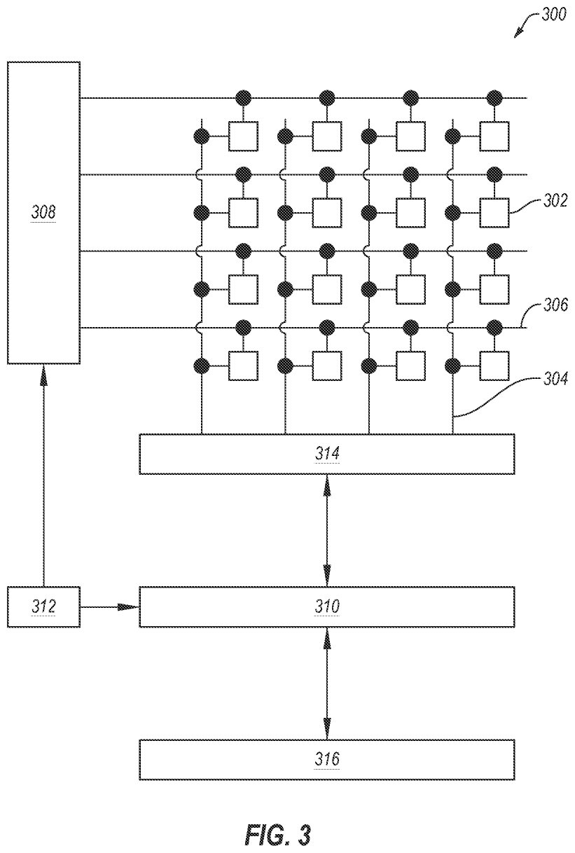

An apparatus (e.g., the apparatus 100, 200 previously described with reference to FIGS. 1A-2B) may be subjected to additional processing acts to form a microelectronic device 300 containing the apparatus (e.g., the apparatus 100, 200 previously described with reference to FIGS. 1A-2B), as shown in FIG. 3. Such additional processing acts may employ conventional processes and conventional processing equipment. The microelectronic device 300 may include, for example, one or more of the apparatus 100, 200 previously described herein. FIG. 3 shows a functional block diagram of the microelectronic device 300 (e.g., a DRAM device, a memory device), in accordance with embodiments of the disclosure. As shown in FIG. 3, the microelectronic device 300 includes memory cells 302, digit lines 304, word lines 306, a row decoder 308, a column decoder 310, a memory controller 312, a sense device 314, and an input/output device 316. The memory cells 302 may include one or more of the apparatus 100, 200.

The memory cells 302 of the microelectronic device 300 are programmable to at least two different logic states (e.g., logic 0 and logic 1). Each memory cell 302 may individually include a capacitor and a transistor. The capacitor stores a charge representative of the programmable logic state (e.g., a charged capacitor may represent a first logic state, such as a logic 1; and an uncharged capacitor may represent a second logic state, such as a logic 0) of the memory cell 302. The transistor grants access to the capacitor upon application (e.g., by way of one of the word lines 306) of a minimum threshold voltage to a semiconductive channel thereof for operations (e.g., reading, writing, rewriting) on the capacitor. The transistor may be operably coupled to the capacitor by way of a conductive contact structure in electrical communication with and extending between the transistor and the capacitor.

The digit lines 304 are connected to the capacitors of the memory cells 302 by way of the transistors of the memory cells 302. The digit lines 304 may be separated (e.g., electrically isolated) from the conductive contact structures extending between the transistors and the capacitors of the memory cells 302. The word lines 306 extend perpendicular to the digit lines 304, and are connected to gates of the transistors of the memory cells 302. Operations may be performed on the memory cells 302 by activating appropriate digit lines 304 and word lines 306. Activating a digit line 304 or a word line 306 may include applying a voltage potential to the digit line 304 or the word line 306. Each column of memory cells 302 may individually be connected to one of the digit lines 304, and each row of the memory cells 302 may individually be connected to one of the word lines 306. Individual memory cells 302 may be addressed and accessed through the intersections (e.g., cross points) of the digit lines 304 and the word lines 306.

The memory controller 312 may control the operations of the memory cells 302 through various components, including the row decoder 308, the column decoder 310, and the sense device 314. The memory controller 312 may generate row address signals that are directed to the row decoder 308 to activate (e.g., apply a voltage potential to) predetermined word lines 306, and may generate column address signals that are directed to the column decoder 310 to activate (e.g., apply a voltage potential to) predetermined digit lines 304. The memory controller 312 may also generate and control various voltage potentials employed during the operation of the microelectronic device 300. In general, the amplitude, shape, and/or duration of an applied voltage may be adjusted (e.g., varied), and may be different for various operations of the microelectronic device 300.

During use and operation of the microelectronic device 300, after being accessed, a memory cell 302 may be read (e.g., sensed) by the sense device 314. The sense device 314 may compare a signal (e.g., a voltage) of an appropriate digit line 304 to a reference signal in order to determine the logic state of the memory cell 302. If, for example, the digit line 304 has a higher voltage than the reference voltage, the sense device 314 may determine that the stored logic state of the memory cell 302 is a logic 1, and vice versa. The sense device 314 may include transistors and amplifiers to detect and amplify a difference in the signals. The detected logic state of a memory cell 302 may be output through the column decoder 310 to the input/output device 316. In addition, a memory cell 302 may be set (e.g., written) by similarly activating an appropriate word line 306 and an appropriate digit line 304 of the microelectronic device 300. By controlling the digit line 304 while the word line 306 is activated, the memory cell 302 may be set (e.g., a logic value may be stored in the memory cell 302). The column decoder 310 may accept data from the input/output device 316 to be written to the memory cells 302. Furthermore, a memory cell 302 may also be refreshed (e.g., recharged) by reading the memory cell 302. The read operation will place the contents of the memory cell 302 on the appropriate digit line 304, which is then pulled up to full level (e.g., full charge or discharge) by the sense device 314. When the word line 306 associated with the memory cell 302 is deactivated, all of memory cells 302 in the row associated with the word line 306 are restored to full charge or discharge.

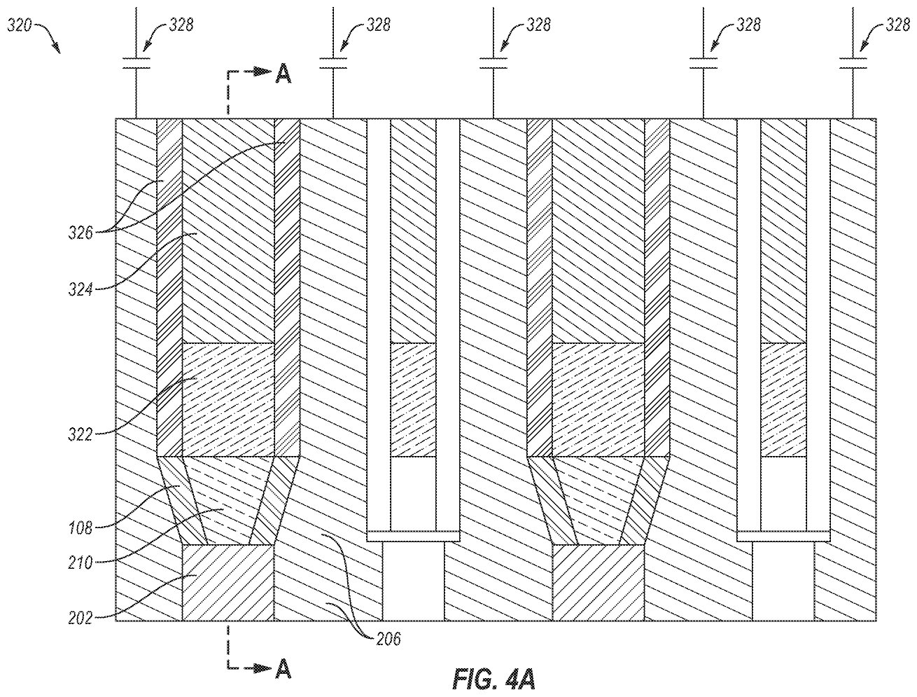

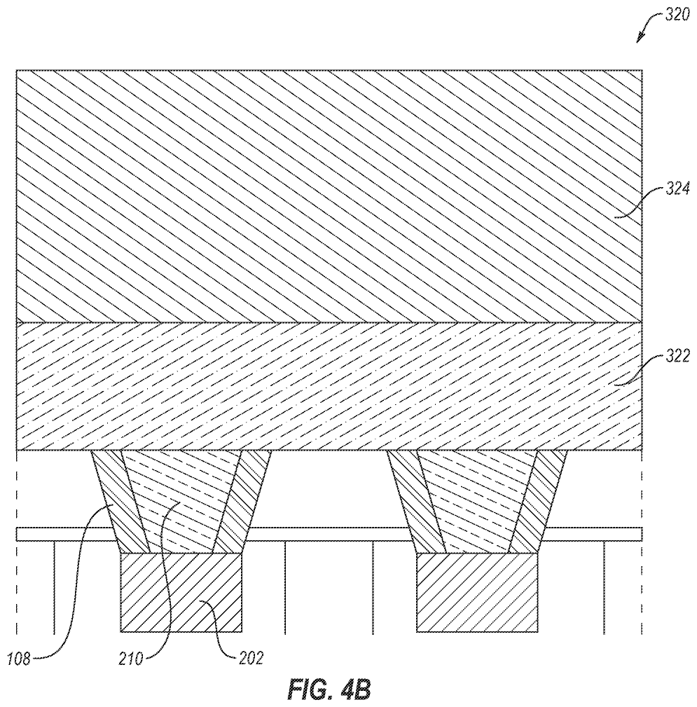

An apparatus (e.g., the apparatus 200 previously described with reference to FIGS. 2A-2B) may be subjected to additional processing acts to form a microelectronic device 320 containing the apparatus (e.g., the apparatus 200 previously described with reference to FIGS. 2A-2B), as shown in FIGS. 4A-4B. Such additional processing acts may employ conventional processes and conventional processing equipment. The microelectronic device 320 may include, for example, one or more of the apparatus 200 previously described. FIGS. 4A-4B shows a diagrammatic cross-sectional view of a portion of microelectronic device 320 (e.g., a DRAM device, a memory device), in accordance with embodiments of the disclosure. As shown in FIGS. 4A-4B, the microelectronic device 320 includes liner 108, first material 202, dielectric material 206, second material 210, digit lines 322, insulative cap material 324, spacers 326, and capacitors 328. The first material 202 may be located adjacent (e.g., laterally adjacent) to dielectric material 206. The second material 210 may be located adjacent (e.g., vertically adjacent) to the first material 202 and the liner 108 may be located adjacent to second material 210 and over first material 202. The digit lines 322 may be located adjacent (e.g., vertically adjacent) to and over the second material 210. The insulative cap material 324 may be located adjacent (e.g., vertically adjacent) to and over the digit lines 322. The spacers 326 may be laterally adjacent to the second material 210, the digit lines 322, and the insulative cap material 324. The dielectric material 206 may be laterally adjacent to the liner 108, the first material 202, and the spacers 326. The capacitors 328 may be electrically connected to the digit lines 322, the second material 210, and the first material 202. FIG. 4B shows cross-sectional view A-A of microelectronic device 320.

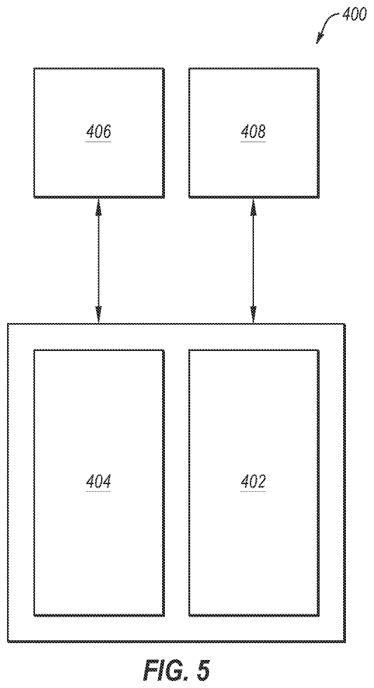

Apparatuses (e.g., the apparatus 100, 200) and microelectronic devices (e.g., the microelectronic devices 300, 320 previously described with reference to FIGS. 3, 4A-4B) may be used in embodiments of electronic systems according to embodiments of the disclosure. Additional processing acts may be performed to form the electronic systems that contain one or more apparatus 100, 200 or one or more microelectronic devices 300, 320. For example, FIG. 5 is a block diagram of an illustrative electronic system 400 according to embodiments of the disclosure. The electronic system 400 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 400 includes at least one memory device 402. The memory device 402 may comprise, for example, an embodiment of one or more of an apparatus (e.g., the apparatus 100, 200) and a microelectronic device (e.g., the microelectronic device 300, 320). The electronic system 400 may further include at least one electronic signal processor device 404 (often referred to as a “microprocessor”). The electronic signal processor device 404 may, optionally, include an embodiment of an apparatus (e.g., the apparatus 100, 200 previously described with reference to FIGS. 1A-2B) and a microelectronic device (e.g., the microelectronic devices 300, 320 previously described with reference to FIGS. 3, 4A-4B) previously described herein. The electronic system 400 may further include one or more input devices 406 for inputting information into the electronic system 400 by a user, such as, for example, a mouse or other pointing device, a keyboard, a touchpad, a button, or a control panel. The electronic system 400 may further include one or more output devices 408 for outputting information (e.g., visual or audio output) to a user such as, for example, a monitor, a display, a printer, an audio output jack, a speaker, etc. In some embodiments, the input device 406 and the output device 408 may comprise a single touchscreen device that can be used both to input information to the electronic system 400 and to output visual information to a user. The input device 406 and the output device 408 may communicate electrically with one or more of the memory device 402 and the electronic signal processor device 404.

The apparatuses (e.g., the apparatus 100, 200 (FIGS. 1A-2B)), microelectronic devices (e.g., the microelectronic device 300, 320 (FIGS. 3, 4A-4B)), electronic systems (e.g., the electronic system 400 (FIG. 5)), and methods of the disclosure facilitate improved performance, reduced costs (e.g., manufacturing costs, material costs), increased miniaturization of components, and greater packing density as compared to conventional structures, conventional apparatuses, conventional devices, conventional systems, and conventional methods. The structures, apparatuses, microelectronic devices, electronic systems, and methods of the disclosure may improve scalability, efficiency, and simplicity as compared to conventional structures, conventional apparatuses, conventional devices, conventional systems, and conventional methods.

Accordingly, an apparatus is disclosed and comprises at least one microelectronic device. The at least one microelectronic device comprises a first material within a first opening in a dielectric material, and a silicon carbide material on sidewalls of the dielectric material. The sidewalls of the dielectric material define a second opening and the silicon carbide material is adjacent to the first material. A second material is within the second opening in the dielectric material and adjacent to the silicon carbide material and the first material. The silicon carbide material comprises a carbon content of from about 0.1 atomic percent to about 20 atomic percent.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A method of forming an apparatus, comprising:
forming a silicon carbide material on a patterned material;
subjecting the silicon carbide material to a plasma to expose horizontal portions of the silicon carbide material to the plasma;
selectively removing the horizontal portions of the silicon carbide material; and
removing the patterned material to form a pattern of the silicon carbide material.

2. The method of claim 1, wherein subjecting the silicon carbide material to a plasma to expose horizontal portions of the silicon carbide material to the plasma comprises reducing a carbon content of the horizontal portions of the silicon carbide material.

3. The method of claim 2, wherein reducing the carbon content of the horizontal portions of the silicon carbide material comprises converting the horizontal portions of the silicon carbide material to be substantially free of carbon.

4. The method of claim 1, wherein selectively removing the horizontal portions of the silicon carbide material comprises exposing the horizontal portions of the silicon carbide material to a wet etchant.

5. The method of claim 4, exposing the horizontal portions of the silicon carbide material to a wet etchant comprises exposing the horizontal portions of the silicon carbide material to an aqueous hydrofluoric acid (HF) solution.

6. The method of claim 1, wherein subjecting the silicon carbide material to a plasma to expose horizontal portions of the silicon carbide material to the plasma comprises subjecting the silicon carbide material to an oxygen plasma.

7. The method of claim 1, wherein subjecting the silicon carbide material to a plasma to expose horizontal portions of the silicon carbide material comprises exposing the horizontal portions of the silicon carbide material to the plasma without substantially exposing vertical portions of the silicon carbide material to the plasma.

8. The method of claim 1, wherein forming the silicon carbide material on a patterned material comprises forming the silicon carbide material comprising a carbon content of from about 0.1 atomic percent to about 20 atomic percent.

9. The method of claim 1, wherein forming a silicon carbide material on a patterned material comprises forming the silicon carbide material to exhibit a thickness within a range of from about 1 nm to about 15 nm.

10. The method of claim 1, wherein forming a silicon carbide material on a patterned material comprises forming the silicon carbide material to exhibit a substantially uniform thickness.

11. The method of claim 1, wherein forming a silicon carbide material on a patterned material comprises forming silicon carbide or silicon carbon oxide on the patterned material.

12. The method of claim 1, further comprising using the pattern of the silicon carbide material as a mask to remove exposed portions of the patternable material.

13. A method of forming an apparatus, comprising:
forming a silicon carbon oxide material on a structure comprising a first material and a dielectric material;
exposing the silicon carbon oxide material to a plasma, horizontal portions of the silicon carbon oxide material exposed to a greater concentration of ions of the plasma than vertical portions of the silicon carbon oxide material; and
removing the horizontal portions of the silicon carbon oxide material without substantially removing the vertical portions of the silicon carbon oxide material to expose a portion of the first material.

14. The method of claim 13, wherein exposing the silicon carbon oxide material to a plasma comprises converting the horizontal portions of the silicon carbon oxide material to a silicon oxide material.

15. The method of claim 13, wherein forming a silicon carbon oxide material on a structure comprises conformally forming the silicon carbon oxide material on the first material and the dielectric material.

16. The method of claim 13, further comprising forming a second material on the exposed portion of the first material.

17. An apparatus comprising:
at least one microelectronic device comprising:
a first material within a first opening in a dielectric material;
a silicon carbide material on sidewalls of the dielectric material, the sidewalls of the dielectric material defining a second opening and the silicon carbide material adjacent to the first material;
a second material within the second opening in the dielectric material and adjacent to the silicon carbide material and the first material; and
the silicon carbide material comprising a carbon content of from about 0.1 atomic percent to about 20.0 atomic percent.

18. The apparatus of claim 17, wherein the silicon carbide material exhibits substantially vertical sidewalls.

19. The apparatus of claim 17, wherein corners of the silicon carbide material are substantially square in cross-section.

20. The apparatus of claim 17, wherein heights of the silicon carbide material are substantially similar to one another.

21. The apparatus of claim 17, wherein the silicon carbide material exhibits sloped sidewalls.
